(19) United States
(12) Patent Application Publication
(10) Pub. No.: US 2017/0084880 A1
(43) Pub. Date: Mar. 23, 2017

(54) LARGE AREA DUAL SUBSTRATE PROCESSING SYSTEM

(71) Applicant: Applied Materials, Inc., Santa Clara, CA (US)

(72) Inventors: Shinichi KURITA, San Jose, CA (US); Ikuo MORI, San Jose, CA (US); Robin L. TINER, Santa Cruz, CA (US)

(21) Appl. No.: 15/273,181

(22) Filed: Sep. 22, 2016

Related U.S. Application Data
(60) Provisional application No. 62/222,181, filed on Sep. 22, 2015.

(51) Int. Cl. H01L 51/56; H01L 21/68; C23C 16/04; C23C 16/455; C23C 16/458; H01L 21/683; H01L 21/67

(52) U.S. Cl. CPC H01L 51/56; H01L 21/6838; H01L 21/681; H01L 21/67098; C23C 16/455; C23C 16/4584; C23C 16/042

(57) ABSTRACT

A process chamber for processing a plurality of substrates is provided. The process chamber includes a chamber body having a single substrate transfer opening, a first substrate support mesa disposed in the chamber body, and a second substrate support mesa disposed in the chamber body. Each substrate support mesa is configured to support a substrate during processing. The centers of the first substrate support mesa, the second substrate support mesa, and the opening are linearly aligned.

### CROSS-REFERENCE TO RELATED APPLICATIONS

This application claims benefit of U.S. provisional patent application Ser. No. 62/222,181, filed Sep. 22, 2015, which is hereby incorporated herein by reference.

### BACKGROUND

Field

Embodiments of the disclosure generally relate to a vacuum processing system for vacuum processing large area substrates (e.g., LCD, OLED, and other types of flat panel displays), and more specifically to processing multiple large area substrates in a single process chamber.

Description of the Related Art

Large area substrates are used to produce flat panel displays (i.e., LCD, OLED, and other types of flat panel displays), solar panels, and the like. Large area substrates are generally processed in one or more vacuum processing chambers, where various deposition, etching, plasma processing and other circuit and/or device fabrication processes are performed. The vacuum processing chambers are typically coupled by a common vacuum transfer chamber that contains a robot that transfers the substrates between the different vacuum processing chambers. The assembly of the transfer chamber and other chambers connected to the transfer chamber (e.g., the processing chambers) is often referred to as a processing system.

During a deposition process on a large area substrate, such as a thin-film encapsulation on an OLED flat panel, a corresponding large area mask may be placed between a deposition source and the substrate to prevent material deposition in select locations on the substrate. These masks can be as large as the large area substrates, so a large footprint for the processing system is generally required for processing these large area substrates with the corresponding large area masks. With a large footprint comes high capital costs and high operating costs.

Thus, there is a continuing need for an improved system for processing large area substrates with corresponding large area masks in a cost effective manner.

### SUMMARY

Embodiments of the disclosure generally relate to vacuum processing large area substrates. In one embodiment, a process chamber for processing a plurality of substrates is provided. The process chamber includes a chamber body having a single substrate transfer opening, a first substrate support mesa disposed in the chamber body, and a second substrate support mesa disposed in the chamber body. Each substrate support mesa is configured to support a substrate during processing. The centers of the first substrate support mesa, the second substrate support mesa, and the opening are linearly aligned.

In another embodiment, a system for processing a plurality of substrates is provided. The system includes a transfer chamber, and a plurality of process chambers coupled to the transfer chamber. At least a first process chamber of the plurality of process chambers includes a first substrate support mesa and a second substrate support mesa. Each substrate support mesa is configured to support a substrate during processing. The first process chamber further includes a first wall having an opening configured to allow transfer of substrates between the substrate support mesas and the transfer chamber. The centers of the first substrate support mesa, the second substrate support mesa and opening are linearly aligned.

In another embodiment, a method of processing a plurality of substrates is provided. The method includes placing a first substrate and a second substrate in a process chamber through an opening in a first wall of the process chamber, wherein a length of each substrate is substantially parallel to the first wall of the process chamber, and depositing one or more layers on the first substrate and the second substrate in the process chamber, wherein the first substrate and the second substrate are disposed horizontally during the deposition.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a top cross-sectional view of a processing system for vacuum processing a plurality of substrates, according to one embodiment.

FIG. 2A is a top cross-sectional view of one of the process chambers of the processing system of FIG. 1, according to one embodiment.

FIG. 2B is a side cross-sectional view of the process chamber of FIG. 2A taken along section line 2B-2B of FIG. 2A.

FIG. 2C is a perspective view of a pair of mask frames and corresponding vision alignment modules, according to another embodiment.

FIGS. 3A-3D illustrate an exemplary substrate exchange sequence in the processing system of FIG. 1, according to one embodiment.

FIGS. 4A-4H illustrate an exemplary mask exchange sequence in the processing system of FIG. 1, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure generally relate to a vacuum processing system for vacuum processing large area substrates (e.g., LCD, OLED, and other types of flat panel displays). Although a vacuum processing system for performing depositions on large area substrates is described herein, the vacuum processing system may alternatively be configured to perform other vacuum processes on substrates, such as etching, on implantation, annealing, plasma treating, and physical vapor depositions among other processes.

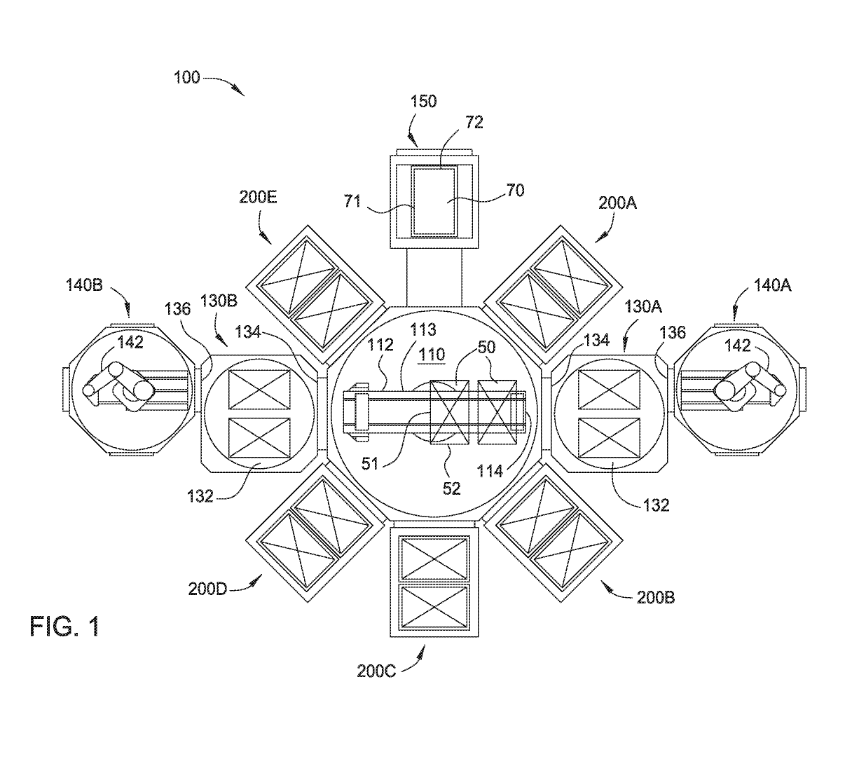

FIG. 1 is a top cross-sectional view of a processing system 100 for performing vacuum processing on a plurality of substrates 50, according to one embodiment of the disclosure. A plurality of masks 70 may optionally be utilized during the processes performed in the processing system 100 as further described below. The processing system 100 includes a central transfer chamber 110, five process chambers 200(A-E), rotation chambers 130(A, B), and an optional mask chamber 150. The two rotation chambers 130(A, B) may be further coupled to two auxiliary transfer chambers 140(A, B). Although five process chambers 200(A-E) are shown, more or less process chambers 200 may be included in the processing system 100. The mask chamber 150 can be used to store a plurality of masks 70 to be used in the processes, such as depositions, performed in the different process chambers 200. For example, the mask chamber 150 may store from about 4 to about 30 masks.

A transfer robot 112 is disposed in the transfer chamber 110 and can be used to move the substrates 50 and the masks 70 to and from the chambers that surround the transfer chamber 110, such as the process chambers 200, the rotation chambers 130, and the mask chamber 150. The transfer robot 112 is capable of moving two substrates 50 or two masks 70 at the same time to or from one of the chambers that surround the transfer chamber 110. For example, the transfer robot 112 is shown supporting two substrates 50 in FIG. 1. The end effector of the transfer robot 112 can have a length 113 and a width 114. The length 113 is parallel to the radial direction in which the transfer robot 112 can extend, for example, radially from a central axis of the robot 112 into one of the process chambers 200, while the width 114 of the end effector is perpendicular to radial extension direction. In some embodiments, the transfer robot 112 can include an upper end effector (not shown) and a lower effector (not shown) that can allow the transfer robot 112 to move substrates 50 and/or masks 70 independently from each other on the different end effectors. In some embodiments, the end effectors can be used to move two substrates 50 or two masks 70 simultaneously.

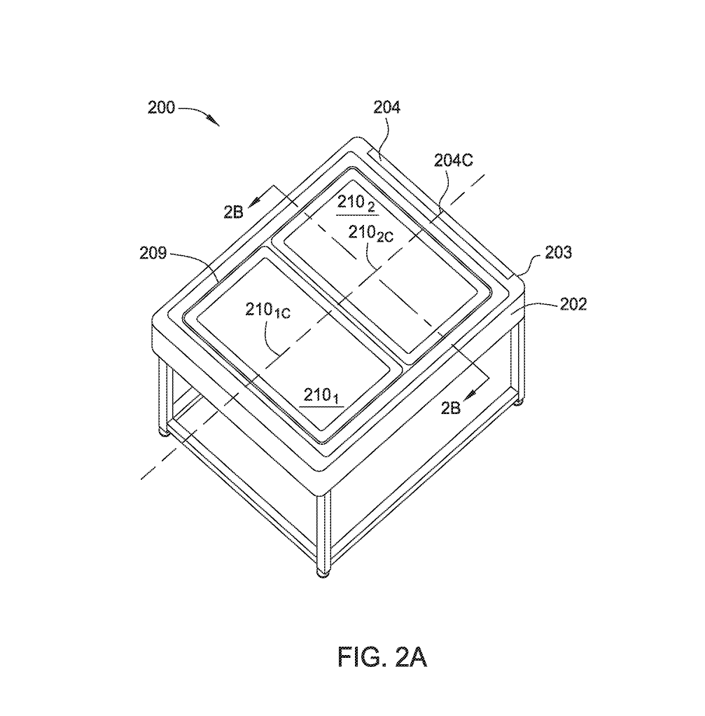

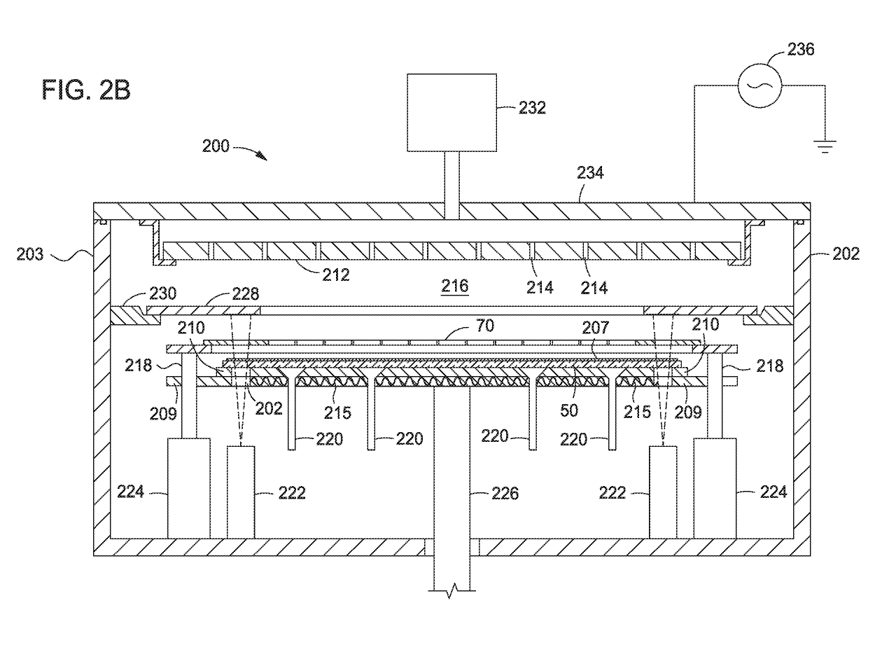

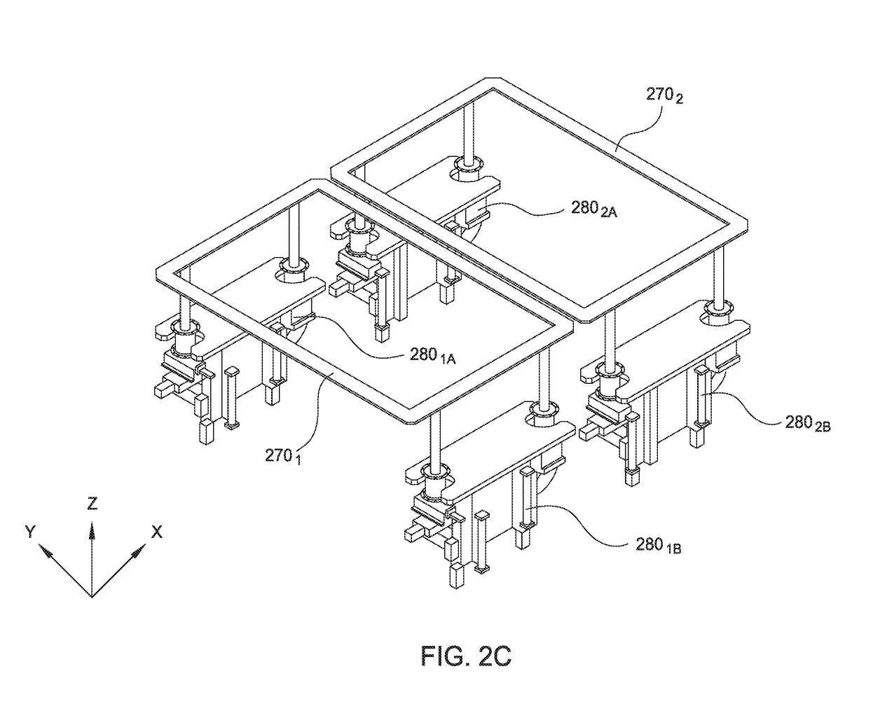

The process chambers 200 (A-E) can each be a chemical vapor deposition (CVD) chamber, a plasma enhanced CVD chamber, or other type of deposition chamber. The process chambers 200 (A-E) can each accommodate two substrates 50 and two masks 70 to enable processes, such as depositions, to be performed on two substrates 50 simultaneously within a single process chamber 200. The process chambers 200 (A-E) are described in further detail below in reference to FIGS. 2A and 2B.

Each rotation chamber 130 (A, B) is provided between a respective auxiliary transfer chamber 140 (A, B) and the transfer chamber 110. The auxiliary transfer chamber 140A may be connected to an upstream part of a larger processing system that includes the processing system 100. The auxiliary transfer chamber 140B may be connected to a downstream part of a larger processing system that includes the processing system 100. The auxiliary transfer chambers 140 (A, B) each include a robot 142 that can transfer a substrate 50 or mask 70 from the auxiliary transfer chamber 140 (A, B) to the adjacent rotation chamber 130 (A, B) or to neighboring upstream or downstream equipment. In some embodiments, one or both of the auxiliary transfer chambers 140 (A, B) can transfer the substrate 50 or mask 70 into a load lock chamber coupled to a factory interface, or to another processing system, such as the processing system 100, among others.

Each substrate 50 has a length 51, a width 52, and a thickness. The length 51 and width 52 are the dimensions of the surface of the substrate 50 on which the processes, such as depositions, are performed in the process chambers 200. The length 51 of the substrate 50 is longer than the width 52 of the substrate 50. In some embodiments, the length 51 of the substrate 50 is longer than the width 52 of the substrate 50 by 50% or more. For example, in one embodiment each substrate 50 has a length of 1500 mm and a width of 925 mm. The thickness is the dimension of the substrate 50 shown in FIG. 2B and may be a few millimeters or less. Furthermore, each mask 70 has a length 71 and a width 72. The length 71 and the width 72 of the mask 70 can be sized similarly to the length 51 and the width 52 of the substrate. The transfer robot 112 is capable of moving the substrates 50 with the length 51 perpendicular or parallel to the length 113 of the end effector of the transfer robot 112. Furthermore, the transfer robot 112 is capable of moving the masks 70 with the length 71 perpendicular or parallel to the length 113 of the end effector of the transfer robot 112. Having the transfer robot 112 able to move the substrates 50 and masks 70 in either 90° orientation (i.e., in an orientation having the length 51 of the substrate 50 perpendicular to or parallel to the direction of radial extension of the end effector of the transfer robot 112) allows for the transfer robot 112 to be used with chambers that provide access to the substrates 50 and/or masks 70 in either 90° orientation, which can reduce the capital costs for the processing system 100. Furthermore, the transfer robot 112 can support two substrates 50 when the width 52 of the substrates 50 are substantially parallel to the length 113 of the end effector of the transfer robot 112. Similarly, the transfer robot 112 can support two masks 70 when the width 72 of the masks 70 are substantially parallel to the length 113 of the end effector of the transfer robot 112.

Each robot 142 can transfer a substrate 50 or mask 70 from one of the auxiliary transfer chambers 140 (A, B) through an opening in one of the walls 136 of the rotation chambers 130 (A, B). The opening of one of the walls 136 of one of the rotation chambers 130 (A, B) can be sized to accommodate the width 52 of the substrate 50 and the width 72 of the mask 70. The opening of one of the walls 136 of one of the rotation chambers 130 (A, B) can be an opening of a door or slit valve between one of the auxiliary transfer chambers 140 (A, B) and one of the rotation chambers 130 (A, B). Thus, the opening may be closed when a substrate 50 or mask 70 is not being transferred between one of the auxiliary transfer chambers 140 and the adjacent rotation chamber 130.

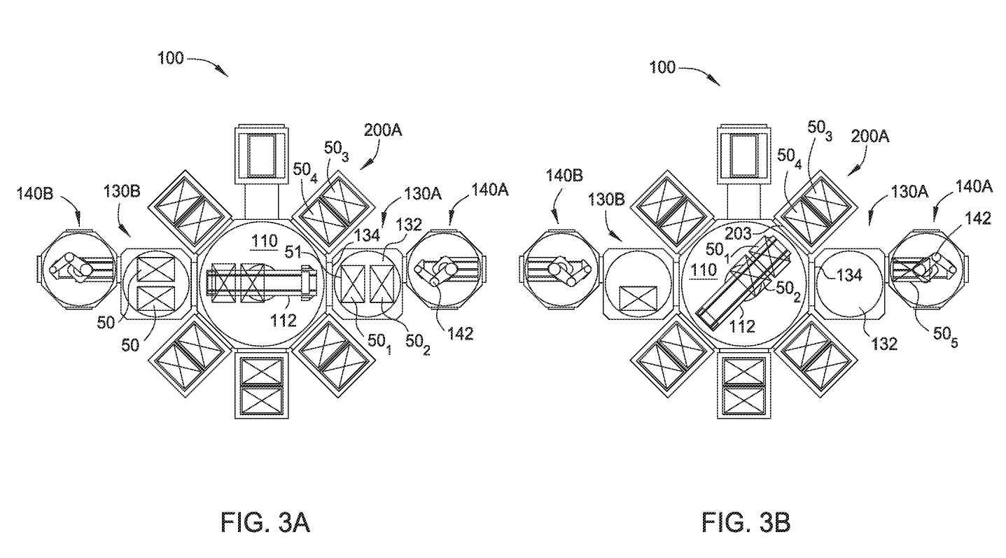

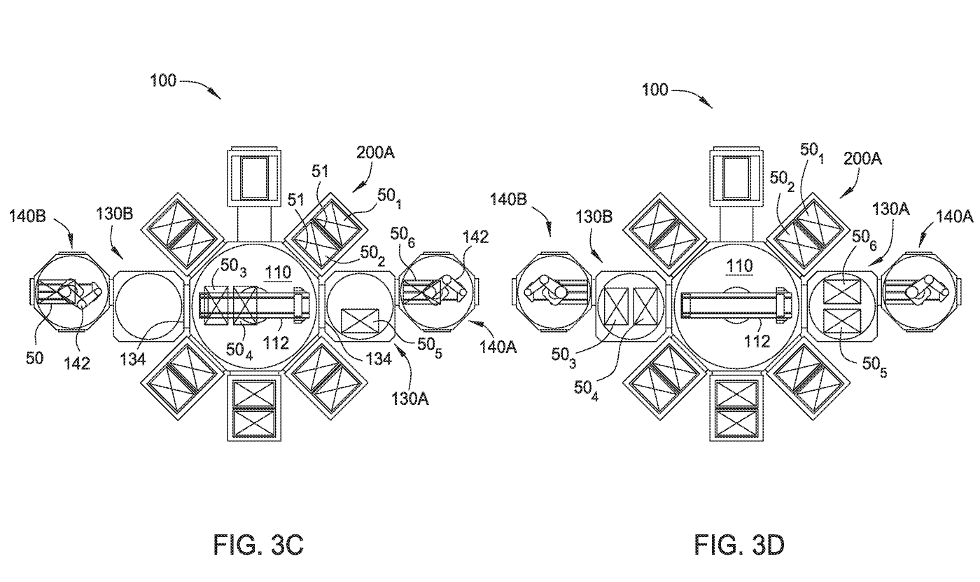

Each rotation chamber 130 (A, B) includes a rotatable stage 132. Two substrates 50 or two masks 70 can be placed adjacent to each other on one of the rotatable stages 132. In one embodiment, one of the robots 142 places one substrate 50 on one of the rotatable stages 132 through a first opening of one of the walls 136, the stage 132 rotates by 180°. This first opening can have a width that is slightly longer than the width 52 of the substrates 50 and the width 72 of the masks 70. Next, the robot 142 can then place another substrate 50 on the rotatable stage 132, and the stage 132 can rotate by 90°. Then the transfer robot 112 of the transfer chamber 110 can remove both substrates 50 from the stage 132 at the same time through a second opening through one of the walls 136 of the rotation chamber 130(A, B). This second opening can be centered with the axis of the transfer robot 112 and can have a width that is slightly longer than the length 51 of the substrates 50 and the length 71 of the masks 70. This process is described in further detail in reference to FIGS. 3A to 3D.

FIG. 2A is a top cross-sectional view of one of the process chambers 200 (A-E) of the processing system 100 of FIG. 1, according to one embodiment of the disclosure. The process chamber 200 of FIG. 2A includes a substrates support 209 that includes two substrate support mesas 210₁, 210₂ that can each be used to support one of the substrates 50. The centers 210_{1C}, 220_{2C} of the substrate support mesas 210₁, 210₂ of a given process chamber 200 are linearly aligned with the central axis of the transfer robot 112. Thus, when the transfer robot 112 rotates the end effector in front of that process chamber 200, the end effector may radially extend in a direction that is aligned with the centers 210_{1C}, 220_{2C} of the substrate support mesas 210₁, 210₂ to facilitate the transfer of the substrates 50 and/or masks 70 to and from that process chamber 200.

The process chamber 200 can further include a first wall 203 having an opening 204. The first wall 203 is generally perpendicular to the direction of extension of the transfer robot 112, and perpendicular to an imaginary line passing through the centers 210_{1C}, 220_{2C} of the substrate support mesas 210₁, 210₂. The opening 204 can be the only opening of the process chamber 200 configured for transferring substrates 50 and/or masks 70. The centers 210_{1C}, 220_{2C} of the substrate support mesas 210₁, 210₂ can be linearly aligned with a center 204C of the opening 204. The first wall 203 can face the transfer chamber 110. The opening 204 can be formed by the opening of a slit valve or similar equipment. The opening 204 has a horizontal dimension that is slightly greater than the length 51 of the substrate 50 and the length 71 of the mask 70. The substrate support mesa 210₂ is closer to the opening 204 than the substrate support mesa 210₁ is to the opening 204. The substrate support mesas 210₁, 210₂ are linearly aligned with the opening 204. In some embodiments, the transfer robot 112 can place a first substrate 50 resting on a front of an end effector of the transfer robot 112 on the first substrate support mesa 210₁ and simultaneously place a second substrate 50 resting on a back of the same end effector on the second substrate support mesa 210₂. In other embodiments, the transfer robot 112 can separately load the substrates 50 onto the substrate support mesas 210₁, 210₂.

FIG. 2B is a side cross-sectional view of the process chamber 200 along the section line 2B-2B of FIG. 2A, according to one embodiment of the disclosure. The following description of FIG. 2B is applicable to processing of one of the substrates 50 using one of the masks 70 on either substrate support mesa 210. The substrate 50, during processing, is disposed on the substrate support mesa 210 opposite a diffuser 212. The diffuser 212 includes a plurality of openings 214 to permit processing gas to enter a processing space 216 defined between the diffuser 212 and the substrate 50. The substrate support 209 can include one or more heating elements 215. In some embodiments, one or more of the heating elements 215 can be disposed under each substrate support mesa 210₁, 210₂. In other embodiments, one or more heating elements 215 can be disposed under only one of the substrate support mesas 210₁, 210₂, so that independent control of the heating of each substrate support mesa 210₁, 210₂ can be obtained.

For processing, the mask 70 is initially inserted into the process chamber 200 through the opening 204 in the first wall and is disposed upon multiple motion alignment elements 218. The motion alignment elements 218 were not shown in FIG. 2A in order to not clutter that Figure. The substrate 50 is then also inserted though the opening 204 in the first wall 203 and disposed upon multiple lift pins 220 that can extend through the substrate support mesa 210. The substrate support mesa 210 then raises to meet the substrate 50 so that the substrate 50 is disposed on the substrate support mesa 210.

Once the substrate 50 is disposed on the substrate support mesa 210, one or more visualization systems 222 determine whether the mask 70 is properly aligned over the substrate 50. Each substrate support mesa 210₁, 210₂ can include its own individual alignment system that is independent of the alignment system of the other substrate support mesa 210₁, 210₂, so that the alignment of the substrate 50 and/or mask 70 on one of the substrate support mesas 210₁, 210₂ does not affect the alignment of the substrate 50 and/or mask 70 on the other substrate support mesa 210₁, 210₂. If the mask 70 is not properly aligned, then one or more actuators 224 of an alignment system move one or more of the motion alignment elements 218 to adjust the location of the mask 70. The one or more visualization systems 222 then recheck the alignment of the mask 70. This process of adjusting the position of the mask 70 with the actuators 224 and rechecking the position can be repeated until the mask 70 is properly aligned over the substrate 50.

Once the mask 70 is properly aligned over the substrate 50, the mask 70 is lowered onto the substrate 50, and then the substrate support mesa 210 raises through movement of a connected shaft 226 until the mask 70 contacts a shadow frame 228. The shadow frame 228, prior to resting on the mask 70, is disposed in the chamber body 202 on a ledge 230 that extends from one or more interior walls of the chamber body 202. The substrate support mesa 210 continues to rise until the substrate 50, the mask 70 and the shadow frame 228 are disposed in a processing position. Processing gas is then delivered from one or more gas sources 232 through an opening formed in a backing plate 234 above the diffuser 212 while an electrical bias can be provided to the diffuser 212 with a radio frequency source 236. One or more layers 207 can be deposited on two substrates 50 in the processing chamber 200 using the process described above with a mask 70 disposed above each substrate 50. For example, in some embodiments, one or more of the layers 207 may be silicon nitride, silicon oxide, and silicon oxynitride.

FIG. 2C is a perspective view of a pair of mask frames 270₁, 270₂ and corresponding vision alignment modules 280_{1A,1B}, 280_{2A,2B}, according to another embodiment. The mask frames 270₁, 270₂ and the vision alignment modules 280_{1A,1B}, 280_{2A,2B} can be used in place of or in combination with the motion alignment elements 218, the actuators 224, and the visualization systems 222 described above in reference to FIG. 2B. The masks 70 (see FIG. 2B) can be placed on the corresponding mask frames 270₁, 270₂ before processing of the corresponding substrates 50 (see FIG. 2B). The vision alignment modules 280_{1A,1B}, 280_{2A,2B} can move the corresponding mask frames 270₁, 270₂ in the X, Y, and Z directions to ensure that the masks 70 are properly aligned over the substrates 50 for processing. The vision alignment modules 280_{1A,1B}, 280_{2A,2B} can each include one or more sensors to confirm that the masks 70 are properly positioned over the substrates 50.

FIGS. 3A-3D illustrate an exemplary substrate exchange sequence in the processing system 100, according to one embodiment. In FIG. 3A, a first substrate 50₁ and a second substrate 50₂ have been placed in the rotation chamber 130A from the auxiliary transfer chamber 140A. The first substrate 50₁ and the second substrate 50₂ are received in the rotation chamber 130A with the lengths 51 of the first substrate 50₁ and the second substrate 50₂ substantially perpendicular to a first wall 134 of the rotation chamber 130A. The first wall 134 can face the transfer chamber 110. The stage 132 of each rotation chamber 130 (A, B) is then rotated, such as by about 90°, to make the length 51 of each substrate 50₁, 50₂ substantially parallel to the first wall 134 of the first rotation chamber 130A (i.e., the position of the substrates 50₁, 50₂ shown in FIG. 3A). These rotation chambers 130 (A, B) allow for the orientation of the substrates 50 and masks 70 to be switched between orientations where the length of the substrate or mask is parallel to the first wall 134 of the rotation chambers 130 (A, B) and where the length 51 of the substrate 50 or length 71 of the mask 70 is perpendicular to the first wall 134 of the rotation chamber 130 (A, B). This capability provided by the rotation chambers 130 (A, B) allows for the substrates 50 and masks 70 to easily be transferred between the process chambers 200 (A-E), the upstream and downstream equipment, and the mask chamber 150.

Furthermore in FIG. 3A, a third substrate 50₃ and a fourth substrate 50₄ are disposed in the process chamber 200A and are ready to be removed, for example, after a process is completed. Also, two additional substrates 50 may be located in the rotation chamber 130B. Although reference is made to specific substrates (e.g., first substrate 50₁) in the description of FIGS. 3A to 3D, any of the operations described in reference to FIGS. 3A to 3D can be performed on any of the substrates 50.

At FIG. 3B, one of the substrates 50 has been removed from the rotation chamber 130B by the robot 142 of the auxiliary transfer chamber 140B. Also, the first substrate 50₁ and the second substrate 50₂ have been removed from the rotation chamber 130A through the opening in the first wall 134 of the rotation chamber 130A by the transfer robot 112 of the transfer chamber 110. Also, the transfer robot 112 has rotated to a position in front of the process chamber 200A with the first substrate 50₁ and the second substrate 50₂ on the transfer robot 112. Furthermore, the robot 142 of the auxiliary transfer chamber 140A has received a fifth substrate 50₅ from upstream equipment.

At FIG. 3C, the first substrate 50₁ and the second substrate 50₂ have been exchanged with the third substrate 50₃ and the fourth substrate 50₄ in the process chamber 200A. The first substrate 50₁ and the second substrate 50₂ have been placed in the process chamber 200A together through the opening 204 of the first wall 203 (See FIG. 2A) of the process chamber 200A by the transfer robot 112. The length 51 of each substrate 50₁, 50₂ is substantially parallel to the first wall 203 of the process chamber 200A. The first substrate 50₁ is horizontally spaced apart from the second substrate 50₂ in the process chamber 200A. By positioning the lengths 51 of the substrates 50 perpendicular to the front wall (i.e., the first wall 203) of the process chambers 200, two substrates 50 can be processed in one process chamber 200, and the amount of area used for the interface between the transfer chamber 110 and the process chambers 200 is substantially less than if the substrates 50 were positioned with the lengths 51 of the substrates 50 perpendicular to the front wall (i.e., the first wall 203) of the process chamber 200. Thus, a large number of substrates 50 can be processed while keeping the footprint o the processing system 100 small, which reduces the costs of the processing system 100.

Furthermore, at FIG. 3C, the third substrate 50₃ and the fourth substrate 50₄ have been removed from the process chamber 200A by the transfer robot 112. The third substrate 50₃ and the fourth substrate 50₄ have also been rotated to be in front of the rotation chamber 130B. The rotation chamber 130B has also rotated by 180° and the robot 142 of the auxiliary transfer chamber 140B has removed the remaining substrate 50 from the rotation chamber 130B. Furthermore, the robot 142 of the auxiliary transfer chamber 140A has placed the fifth substrate 50₅ in the rotation chamber 130A. Also, the robot 142 of the auxiliary transfer chamber 140A has received a sixth substrate 50₆ from upstream equipment.

At FIG. 3D, the transfer robot 112 has placed the third substrate 50₃ and the fourth substrate 50₄ in the rotation chamber 130B. The stage 132 of the rotation chamber 130B can rotate by about 90° for removal of one of the substrates 50₃, 50₄, and then the stage 132 of the rotation chamber 130B can rotate by about 180° for removal of the remaining substrate 50₃, 50₄ from the rotation chamber 130B. Furthermore, the rotation chamber 130A has rotated by 180°, and the robot 142 of the auxiliary transfer chamber 140A has placed the sixth substrate 50₆ in the rotation chamber 130A. The process from FIGS. 3A to 3D can then be repeated when the next process in one of the process chambers 200 (A-E) finishes and a pair of substrates 50 are ready to be removed from the processing system 100.

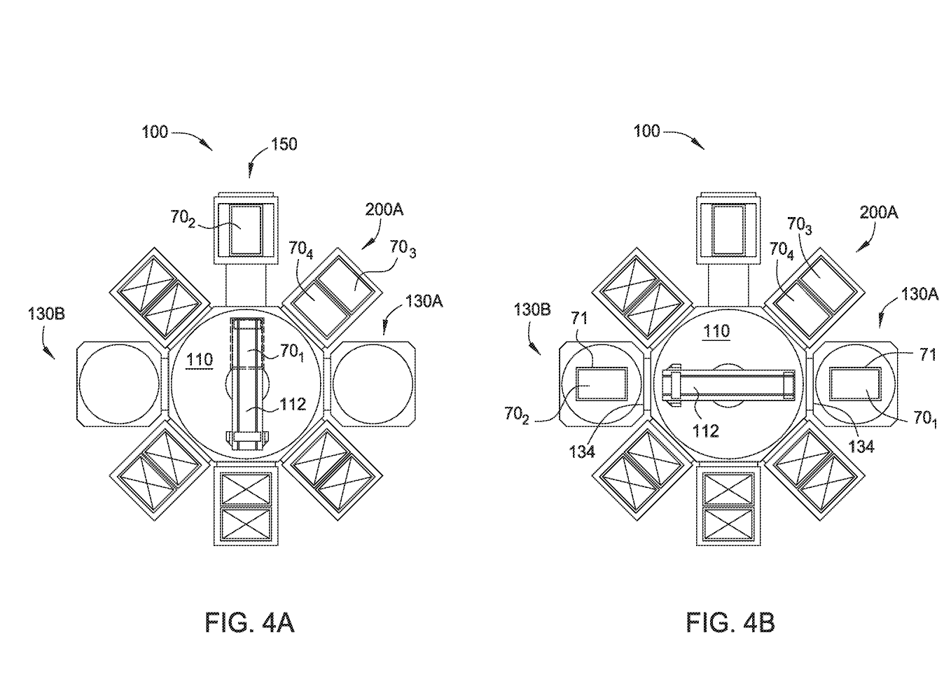

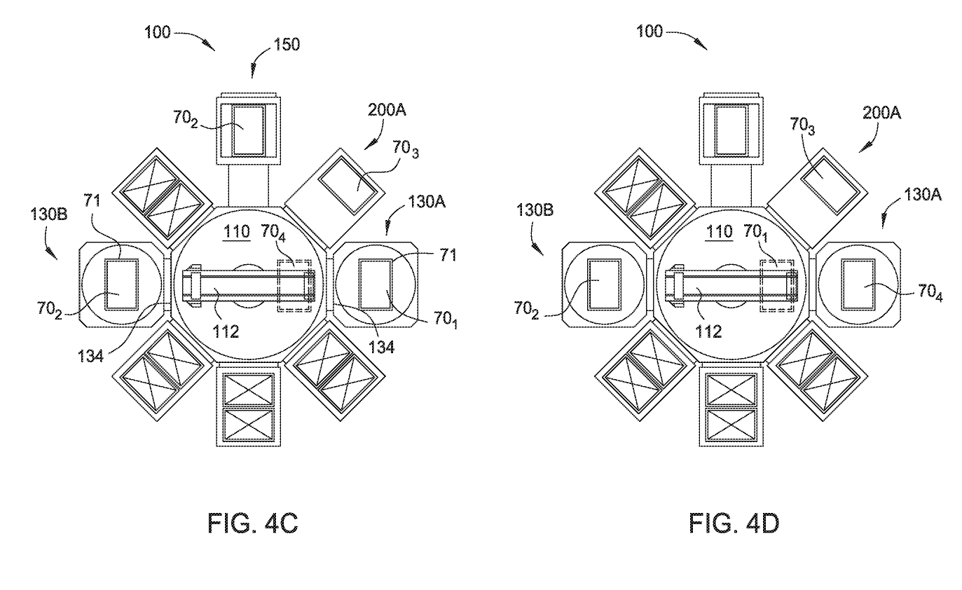

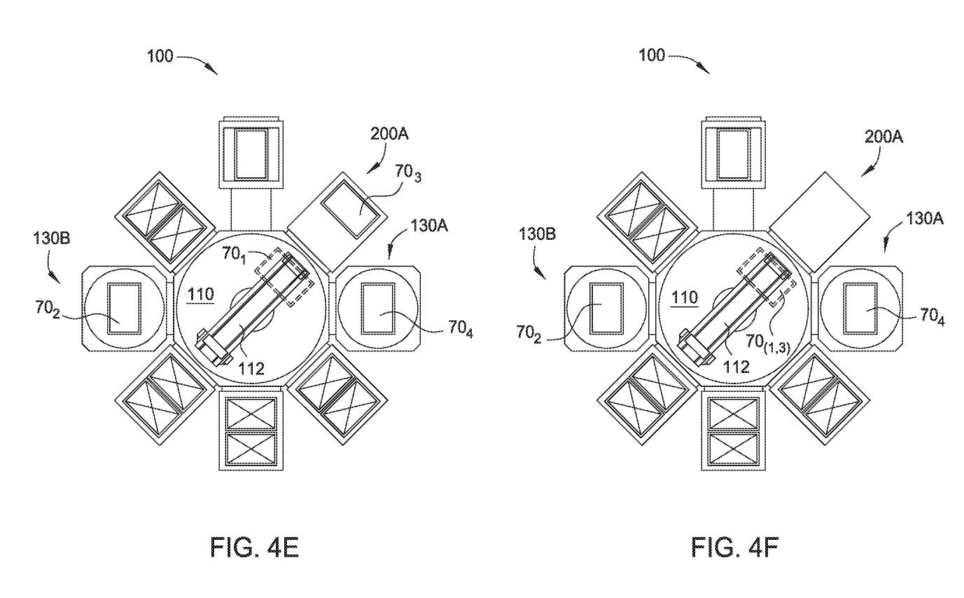

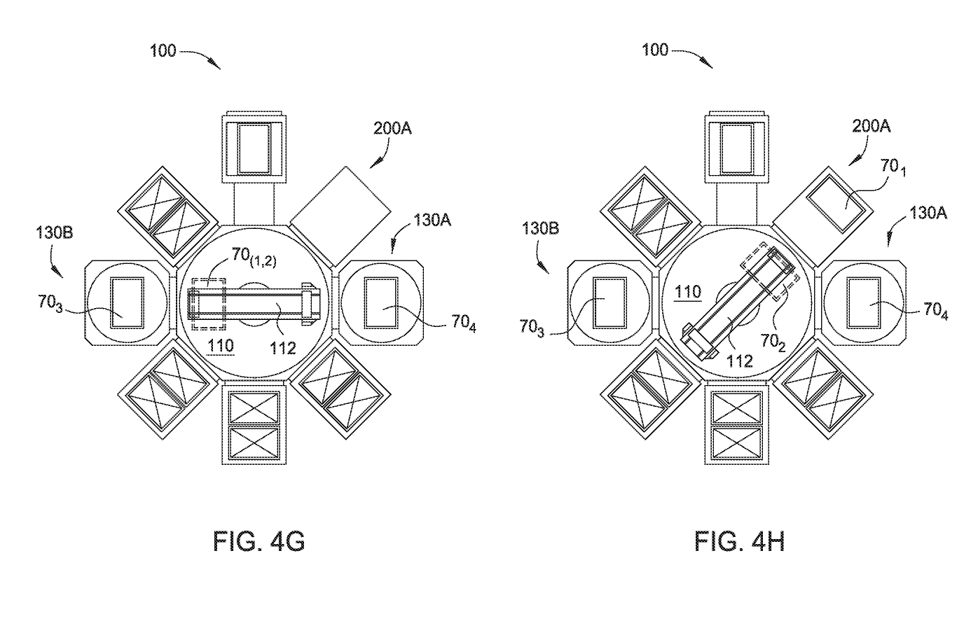

FIGS. 4A-4H illustrate an exemplary mask exchange sequence in the processing system 100. At FIG. 4A, a first mask 70₁ is removed from the mask chamber 150 by the transfer robot 112 and a second mask 70₂ remains in the mask chamber 150. Also, a process has been completed in process chamber 200A and a third mask 70₃ and a fourth mask 70₄ remain in the process chamber 200A. Although reference is made to specific masks (e.g., first mask 70₁) in the description of FIGS. 4A to 4H, any of the operations described in reference to FIGS. 4A to 4H can be performed on any of the masks 70.

At FIG. 4B, the transfer robot 112 has placed the first mask 70₁ into the rotation chamber 130A. The length 71 of the first mask 70₁ is substantially perpendicular to the first wall 134 of the rotation chamber 130A. The transfer robot 112 has also removed the second mask 70₂ from the mask chamber 150. The transfer robot 112 has placed the second mask 70₂ into the rotation chamber 130B. The length 71 of the second mask 70₂ is substantially perpendicular to the first wall 134 of the rotation chamber 130B.

At FIG. 4C, the transfer robot 112 has removed the fourth mask 70₄ from the process chamber 200A. The transfer robot 112 has also rotated the fourth mask 70₄ to be in front of the rotation chamber 130A. Also, the stage 132 of each rotation chamber 130 (A, B) has been rotated by about 90°, so that the length 71 of each mask 70₁, 70₂ is substantially parallel to the first wall 134 of the rotation chamber 130 (A, B) in which the mask 70₁, 70₂ is placed.

At FIG. 4D, the transfer robot 112 has removed the first mask 70₁ from the rotation chamber 130A through the opening in the first wall 134 of the rotation chamber 130A. The transfer robot 112 has also placed the fourth mask 70₄ into the rotation chamber 130A.

At FIG. 4E, the transfer robot 112 has rotated the first mask 70₁ to be in front of the process chamber 200A. At FIG. 4F, the transfer robot 112 has removed the third mask 70₃ from the process chamber 200A. For example, in one embodiment, the first mask 70₁ can be on an upper end effector of the transfer robot 112, and the third mask 70₃ can be on a lower end effector of the transfer robot 112.

At FIG. 4G, the transfer robot 112 has rotated the first mask 70₁ and the third mask 70₃ to be in front of the rotation chamber 130B. The transfer robot 112 has removed the second mask 70₂ from the rotation chamber 130B through the opening in the first wall 134 of the rotation chamber 130B. The transfer robot 112 has also placed the third mask 70₃ into the rotation chamber 130B.

At FIG. 4H, the transfer robot 112 has rotated the first mask 70₁ and the second mask 70₂ to be in front of the process chamber 200A. The transfer robot 112 has placed the first mask 70₁ in the process chamber 200A through the opening 204 in the first wall 203 (See FIG. 2A) of the process chamber 200A. The transfer robot 112 can then place the second mask 70₂ into the process chamber 200A through the opening 204 in the first wall 203 (See FIG. 2A) of the process chamber 200A. The first mask 70₁ can be horizontally spaced apart from the second mask 70₂ in the process chamber 200A. Although not shown, the third mask 70₃ and the fourth mask 70₄ can then be rotated by about 90°, and the masks 70₃, 70₄ can then be placed back in the mask chamber 150 by the transfer robot 112.

The processing system described above allows for processes to be performed on a large number of substrates while only using a relatively small footprint. By positioning the lengths of the substrates perpendicular to the front wall of the process chambers, two substrates can be processed in one process chamber and the amount of area used for the interface between the transfer chamber and the process chambers is substantially less than if the substrates were positioned with the lengths of the substrates perpendicular to the front wall of the process chamber. Furthermore, the rotation chambers allow for the orientation of the substrates and masks to be switched between orientations where the length of the substrate or mask is parallel to the front wall of the rotation chambers and where the length of the substrate or mask is perpendicular to the front wall of the rotation chamber. This capability provided by the rotation chambers allows for the substrates and masks to easily be transferred between the process chambers, the upstream and downstream equipment, and the mask chamber.

While the foregoing is directed to embodiments of the present disclosure, other and further embodiments of the disclosure may be devised without departing from the basic scope thereof, and the scope thereof is determined by the claims that follow.

1. A process chamber for processing a plurality of substrates comprising:
a chamber body having a single substrate transfer opening;
a first substrate support mesa disposed in the chamber body; and
a second substrate support mesa disposed in the chamber body, each substrate support mesa configured to support a substrate during processing;
wherein centers of the first substrate support mesa, the second substrate support mesa, and the opening are linearly aligned.

2. The process chamber of claim 1, further comprising:
a first alignment system is configured to align a mask over a substrate disposed on the first substrate support mesa; and
a second alignment system independently operable relative to the first alignment system, the second alignment system configured to align a mask over a substrate disposed on the second substrate support mesa.

3. The process chamber of claim 2, wherein each alignment system comprises:
one or more visualization systems configured to view alignment of the mask relative to the substrate.

4. The process chamber of claim 1 further comprising:
a substrate support that includes the first substrate support mesa and the second substrate support mesa.

5. The process chamber of claim 4 further comprising:
a heating element disposed under both substrate support mesas.

6. The process chamber of claim 4 further comprising:
multiple heating elements, wherein each heating element is disposed under both substrate support mesas.

7. The process chamber of claim 4 further comprising:
a first heating element disposed under the first substrate support mesa; and
a second heating element disposed under the second substrate support mesa, wherein the first heating element is not disposed under the second substrate support mesa and the second heating element is not disposed under the first substrate support mesa.

8. A system for processing a plurality of substrates comprising:
a transfer chamber; and
a plurality of process chambers coupled to the transfer chamber, wherein at least a first process chamber of the plurality of process chambers comprises:
a first substrate support mesa;
a second substrate support mesa, each substrate support mesa configured to support a substrate during processing; and
a first wall having an opening configured to allow transfer of substrates between the substrate support mesas and the transfer chamber, wherein centers of the first substrate support mesa, the second substrate support mesa and opening are linearly aligned.

9. The system of claim 8 further comprising:
a first alignment system is configured to align a mask over a substrate disposed on the first substrate support mesa; and
a second alignment system independently operable relative to the first alignment system, the second alignment system configured to align a mask over a substrate disposed on the second substrate support mesa.

10. The system of claim 9, wherein each alignment system comprises:
one or more visualization systems configured to view the alignment of the mask relative to the substrate.

11. The system of claim 8 further comprising:
a substrate support that includes the first substrate support mesa and the second substrate support mesa.

12. The system of claim 11 further comprising:
a heating element disposed under both substrate support mesas.

13. The system of claim 11 further comprising:
multiple heating elements, wherein each heating element is disposed under both substrate support mesas.

14. The system of claim 11 further comprising:
a first heating element disposed under the first substrate support mesa; and
a second heating element disposed under the second substrate support mesa, wherein the first heating element is not disposed under the second substrate support mesa and the second heating element is not disposed under the first substrate support mesa.

15. The system of claim 8 further comprising:
a first rotation chamber coupled to the transfer chamber, the first rotation chamber including a stage operable to rotate one or more substrates at least 90°.

16. The system of claim 8 further comprising:
a mask chamber coupled to the transfer chamber, the mask chamber configured to store a plurality of masks.

17. A method of processing a plurality of substrates comprising:
placing a first substrate and a second substrate in a process chamber through an opening in a first wall of the process chamber, wherein a length of each substrate is substantially parallel to the first wall of the process chamber; and
depositing one or more layers on the first substrate and the second substrate in the process chamber, wherein the first substrate and the second substrate are disposed horizontally during the deposition.

18. The method of claim 17, further comprising:
placing the first substrate and the second substrate on a stage of a first rotation chamber, wherein the first substrate and the second substrate each have a width, wherein the length is longer than the width;
rotating the stage to make the length of each substrate substantially parallel to a first wall of the first rotation chamber; and
removing the first substrate and the second substrate from the first rotation chamber through an opening in the first wall of the first rotation chamber.

19. The method of claim 18, further comprising:
removing the first substrate and the second substrate from the process chamber;
placing the first substrate and the second substrate on a stage of a second rotation chamber;
rotating the stage of the second rotation chamber by about 90°;
removing the first substrate from the second rotation chamber;
rotating the stage of the second rotation chamber by about 180°; and
removing the second substrate from the second rotation chamber.

20. The method of claim 17, wherein a first mask is disposed above the first substrate and a second mask is disposed above the second substrate during the deposition of at least one of the one or more layers.
